(19) United States
(12) Patent Application Publication
(10) Pub. No.: US 2020/0203470 A1
(43) Pub. Date: Jun. 25, 2020

(54) MAGNETIC MOLD MATERIAL INDUCTORS FOR ELECTRONIC PACKAGES

(71) Applicant: INTEL CORPORATION, Santa Clara, CA (US)

(72) Inventors: Kedar Dhane, Chandler, AZ (US); Malavarayan Sankarasubramanian, Chandler, AZ (US); Yongki Min, Phoenix, AZ (US); William J. Lambert, Tempe, AZ (US)

(73) Assignee: INTEL CORPORATION, Santa Clara, CA (US)

(21) Appl. No.: 16/226,745

(22) Filed: Dec. 20, 2018

(51) Int. Cl. H01L 49/02; H01L 23/522; H01L 23/367; H01L 21/768

(52) U.S. Cl. CPC H01L 28/10; H01L 21/76885; H01L 23/367; H01L 23/5227

(57) ABSTRACT

A conductive metal pillar is disposed within a composite material used as a die overflow material to form inductor on a module substrate. In situ fabrication of inductors on a module substrate enable customized selection of an inductance value, thus enabling inductors (and other similar peripheral devices) to be placed on a module substrate rather than on a motherboard. Furthermore, these in situ fabricated peripheral devices may also be used to remove excess heat produced by a die because the magnetic particles of the composite material are also thermally conductive. Furthermore, electrically conductive elements of the peripheral devices can be placed in contact with the die and/or integrated heat spreader.

### BACKGROUND

Integrated circuitry continues to scale to smaller feature dimensions and higher packaging densities. With such scaling, the density of power consumption of a given microelectronic device within a given package tends to increase, which, in turn, tends to increase the average junction temperature of transistors of that device. If the temperature of the microelectronic device becomes too high, the integrated circuits making up that device may be damaged or otherwise suffer performance issues (e.g., sub-optimal performance such as low gain or slow switching speeds, or catastrophic failure where one or more portions of the integrated circuitry is destroyed). Furthermore, as integrated circuitry scales to smaller features, so to do the electronic packages that house the die on which the integrated circuits are instantiated. The reduced package size complicates the manufacturing of the modules and the integration of peripheral devices such as inductors and voltage regulators on module substrates.

### BRIEF DESCRIPTION OF THE DRAWINGS

FIG. 1 is a method flow diagram of an example method for in situ fabrication of peripheral electronic devices on a module substrate, in accordance with an embodiment of the present disclosure.

FIGS. 2A-2D illustrate various stages of fabrication of an electronic package fabricated according to a first example sub-method illustrated in FIG. 1, in accordance with an embodiment of the present disclosure.

FIGS. 3A-3D illustrate various stages of fabrication of an electronic package fabricated according to a second example sub-method illustrated in FIG. 1, in accordance with an embodiment of the present disclosure.

FIG. 3E is a plan view an example electronic package that includes a periodic array of conductive pillars having hexagonal cross-sections parallel to the plane of the die, in accordance with an embodiment of the present disclosure.

FIGS. 4A-4B illustrate example modules in which some peripheral devices are in thermal contact with one or more die within a module and also in thermal contact with an integrated heat spreader of the module, in accordance with embodiments of the present disclosure.

FIGS. 4C-4D illustrate a cross-sectional view and a plan view, respectively, of a stacked-die module that include peripheral devices, in accordance with an embodiment of the present disclosure.

FIG. 5 illustrates a computing system implemented with one or more in situ fabricated peripheral devices, configured in accordance with an embodiment of the present disclosure.

As will be appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles, and some features may have surface topology or otherwise be non-smooth, given real world limitations of the processing equipment and techniques used.

### DETAILED DESCRIPTION

Microelectronic packages are described in which a composite mold material comprising a matrix that includes magnetic particles, wherein the mold material is molded over a module substrate. In some such embodiments, the matrix can be, for instance, a polymer matrix or a semiconductor matrix or a dielectric matrix or any other suitable mold material. In any such cases, a conductive metal pillar can be disposed within the composite material, wherein the metal pillar includes magnetic particles so as to form an inductor on the module substrate. Example embodiments of inductors and other peripheral devices fabricated in this way can be electrically efficient and physically compact. That is, some examples of peripheral devices fabricated according to some techniques described herein have a smaller footprint than their commercially available mass-produced analogs. This smaller footprint enables the peripheral devices to be fabricated in situ on a module substrate in some situations. This physical proximity between a peripheral device and an associated die can improve the electrical performance of the peripheral device. Furthermore, in some examples the inductance value of inductors of the present disclosure may be selected by configuring a corresponding design of a conductive pillar within the composite material. This customization can reduce the surface area occupied by a peripheral device for a given power rating relative to the surface area occupied by mass-produced peripheral devices. Furthermore, peripheral devices of the present disclosure may also contribute to the removal of heat produced by a die because they are formed from thermally conductive materials that are in close proximity to, or in some cases in thermal contact with, a die and/or an integrated heat spreader.

General Overview

As the complexity and density of integrated circuit devices have increased, greater demands have been placed on electronic packages housing these devices to meet increased performance requirements. For example, power provided to the integrated circuits through the electronic package substrate generally requires more precise regulation as circuit density increases. Also, removing heat from the die becomes more important as circuit density increases because generally more densely packed integrated circuits produce more heat per unit area of die.

These challenges are complicated by the general trend toward smaller form factors for packaged die (often referred to as “modules”) as the size of die also decrease. For example, voltage regulators, inductors, and stand-alone DC-DC power conversion devices are often surface-mounted to a motherboard to which one or more modules are electrically connected because there is often too little space on a module substrate for the peripheral devices. Integrating peripheral devices on a motherboard rather than on a module can lead to decreased performance because of the added conductive distance and electrical resistance between the peripheral device and the die. This can be a factor in particular for die in which voltage regulator circuitry is an element of the integrated circuits on the die itself. Furthermore, while computing performance of a module can be improved by decreasing a physical separation distance between the peripheral device and the die, placing peripheral devices on a motherboard limits how close to a die a peripheral device can be placed.

Placing voltage regulators, inductors, and other similar peripheral devices on a module substrate can improve performance compared to placing the peripheral devices on the motherboard, but integrating peripheral devices onto a module substrate is technologically challenging.

One challenge, indicated above, is the limited surface area available on a surface of a module substrate. Often there is not enough room to attach a peripheral device between an edge of a module substrate and a die. This challenge is compounded by the fact that peripheral devices are often mass-produced in relatively large and bulky form factors, and at a limited number of discrete power ratings. As a result, not only can integrating the bulky peripheral devices on limited module substrate surface area be challenging, there are likely to be more peripheral devices than actually needed by the integrated circuit device because of the limited number of power ratings available commercially. This means that the already limited module substrate surface area is wasted by the addition of peripheral devices that are not fully utilized (for example, adding two 5 nanoHenry inductors to a motherboard requiring only 6 nanoHenry of added inductance).

Thus, in accordance with some example techniques described herein, electronic packages are described in which a mold material comprising a polymer matrix filled with magnetic particles is molded over at least a portion of a module substrate. At least one conductive metal pillar is disposed within the magnetic material to form a peripheral device (e.g., an inductor) on the module substrate. Not only are embodiments of peripheral devices fabricated in this way electrically efficient and compact (e.g., occupying a much smaller footprint than the commercially available mass-produced analogs), but a power rating (e.g., an amount of inductance, a current limit for a DC power converter) can be customized based on the configuration of the peripheral device. For example, an inductance value may be selected by configuring a corresponding design of the inductor that is fabricated in situ on a module substrate using some of the techniques described herein. This ability to customize the peripheral device can reduce the surface area occupied by a peripheral device relative to the surface area occupied by a mass-produced peripheral device. In particular, the inclusion of under-utilized peripheral devices can be avoided, further reducing module substrate surface area occupied by peripheral devices. Furthermore, peripheral devices of the present disclosure may also contribute to the removal of excess heat produced by a die because they are formed from thermally conductive materials that are in close proximity to, or in some cases in thermal contact with, the die and/or an integrated heat spreader.

Method and Architecture

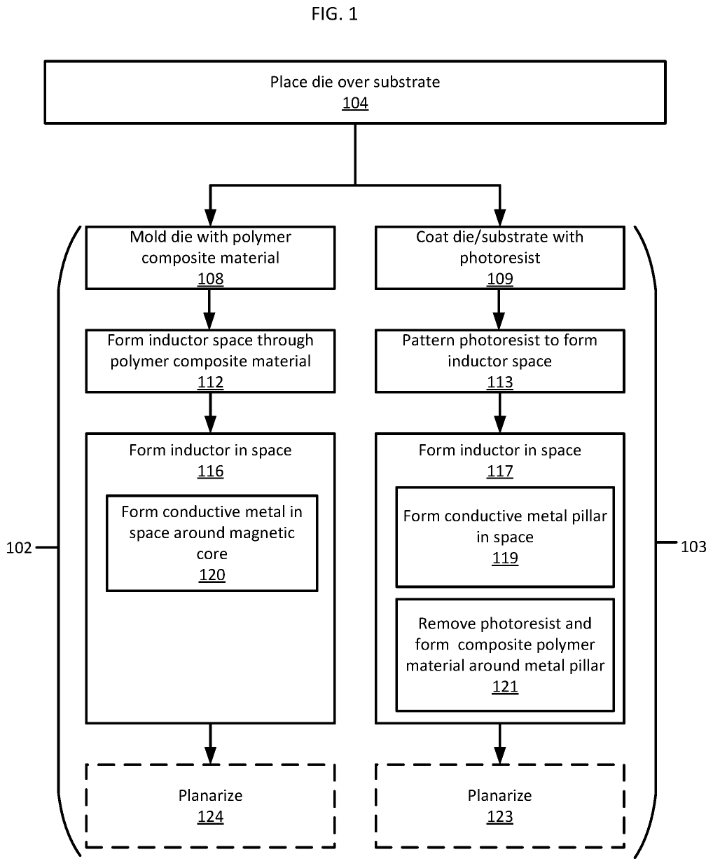

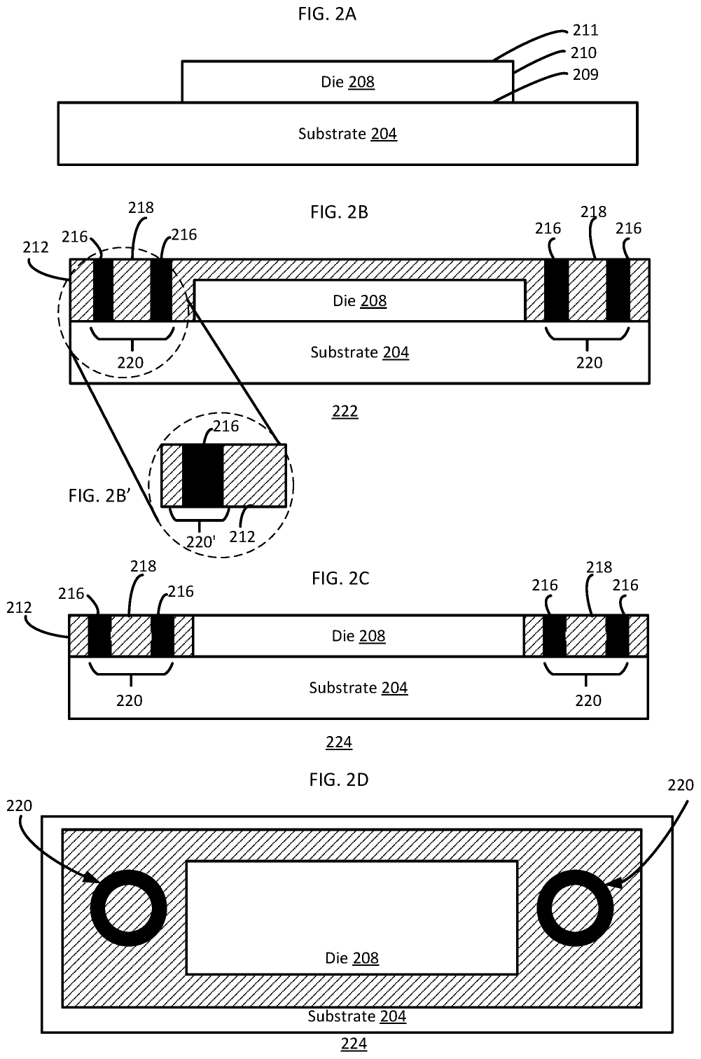

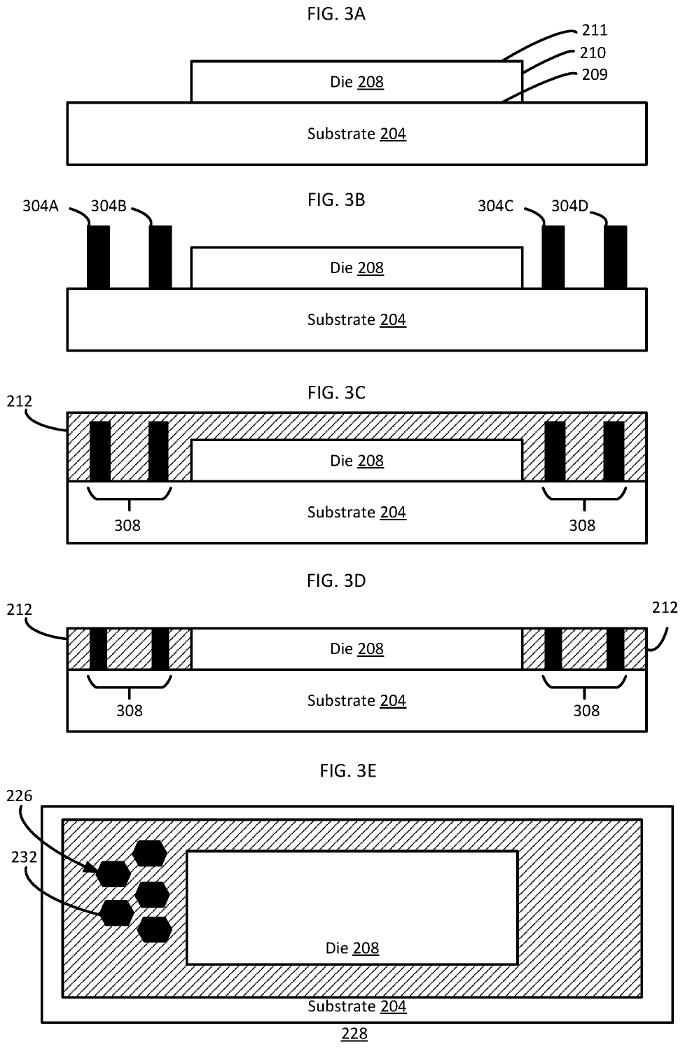

FIG. 1 illustrates a method 100 that includes two alternative techniques (sub-method 102, sub-method 103) for in situ fabrication of peripheral devices on a module substrate, in some embodiments of the present disclosure. Example structures corresponding to the sub-method 102 are illustrated in FIGS. 2A-2D. Example structures corresponding to the sub-method 103 are illustrated in FIGS. 3A-3E. Concurrent reference to FIG. 1 and FIGS. 2A-2D, 3A-3E of the corresponding sub-method will facilitate explanation.

The method 100 begins by placing 104 a die 208 over a module substrate 204. This is illustrated in FIGS. 2A, 3A. The die 208 can be, for example, a portion of a silicon wafer or other semiconducting substrate material (colloquially known as a “chip”) that has been fabricated to include input/output interfaces on a first side 209 of the die 208 that confronts the substrate 204. These input/output interfaces can be used to connect the die 208 to the substrate 204 via, for example, wire bonds or solder bumps (sometimes called flip-chip bumps). A second side 211 of the die 208 is on a side opposite that of the first side 209 and the substrate 204. Sidewalls 210 of the die 208 are also indicated in FIG. 2A (and FIG. 3A). As will be appreciated, the module substrate (or package) 204 can be any type of substrate or package whether ceramic, glass ceramic, polymeric, semiconductor (e.g., silicon), dielectric, combinations thereof (e.g., a composite comprising a polymer matrix that includes layers or elements of a semiconductor material (e.g. silicon)), or some other type of substrate or package suitable for hosting die 208.

For ease of description, substrate or package 204 is hereinafter referred to as module substrate 204 or simply substrate 204. Furthermore, the substrate 204 can be configured for any of a variety of types of die/substrate interconnect technologies, as described above. The module substrate 204 can also be configured to connect to a motherboard (not shown) via package interconnections that include, but are not limited to wire bond, ball grid array (BGA), land grid array (LGA), pin grid array (PGA), among others. As with the die/substrate interconnections, interconnections between the substrate 204 and a motherboard have been omitted from the figures for clarity of depiction. In other embodiments, an interposer or bridge (e.g., silicon interposer or embedded silicon bridge) may be deployed between the die 208 and the substrate or package 204, to facilitate interconnections. In such cases, the interposer or bridge may include any number of routing layers, as will be appreciated.

Continuing the description of the sub-method 102, the die 208 on the substrate 204 is molded 108 with a composite material 212. The composite material includes a mold material (e.g., polymer, or other suitable mold material) and a magnetic material (e.g., iron or other suitable magnetic material). That is, at least the sidewalls 210 and in some cases (as shown) the second surface 211 of the die 208 are covered with composite material 212. In other contexts, a “mold” material may be composed of a thermoplastic polymer, a liquid crystal polymer, or a thermoset polymer, such as an epoxy, and filled with an inorganic filler, such as silica. However, the composite material 212 as used herein can be fabricated from a thermoset polymer (e.g., an epoxy) and magnetic filler particles. The magnetic filler particles, as described below, enable in situ fabrication of peripheral devices including, but not limited to, inductors. The composite material 212 may also include other materials that aid the processing, flow, and curing of the composite material 212.

Examples of thermoset polymers include, but are not limited to, acrylates (e.g., methacrylate), epoxies (e.g., bis-A, bis-F), urethanes, cyano-acrylates, cyano-urethanes, silicones (e.g., polysiloxane) or mixtures thereof. Components in the thermoset polymer matrix that may facilitate processing (e.g, by controlling viscosity during application, facilitating hardening of the polymer matrix after deposition on the die 208) include hardeners, catalysts, cationic, nucleophilic or ultraviolet (UV) polymerization initiators, or a combination thereof. Examples of polymerization initiators can include acids (e.g., carboxylic acid), bases (e.g., amines), peroxides, and/or any photoactivite polymerization initiators (e.g., azobisisobutyronitrile).

The composite material 212 may also include toughening agents, surfactants, adhesion promotors, thixotropic index modifiers, reactive diluents, or other process enabling or property modifiers.

In some examples, the magnetic filler particles include at least one of a metallic magnetic material or a magnetically “soft” (e.g., a low magnetic coercivity of less than 1000 Amperes/meter) ferromagnetic magnetic material. Examples of metallic magnetic materials include, but are not limited to, iron (Fe), oriented iron silicide (FeSi), unoriented FeSi, iron nickel alloys (FeNi), iron cobalt alloys (FeCo), and various intermetallic alloys and compounds such as FeSiBNbCu and/or CoZrTa. Examples of ferromagnetic materials include, but are not limited to, manganese zinc (MnZn), nickel zinc (NiZn), and/or iron (III) oxide (Fe₂O₃). In some examples, the magnetic filler particles have a magnetic permeability from 1 nanoHenry to 10,000 nanoHenrys in a range of from 1 Hz to 10 GHz.

In some examples, the magnetic filler particles within the composite material 212 can have a diameter within any of the following ranges: from 0.1 μm to 10 μm; from 0.1 μm to 2.5 μm; from 2.5 μm to 5 μm; from 5 μm to 10 μm; from 5 μm to 7.5 μm; from 7.5 μm to 10 μm. In some examples the magnetic filler particles within the composite material 212 can compose any of the following volume fraction per unit volume of composite material 212: from 40 volume (vol.) % to 90 vol. %; from 40 vol. % to 60 vol. %; from 50 vol. % to 60 vol. %; from 75 vol. % to 90 vol. %; from 60 vol. % to 90 vol. %.

FIG. 2B illustrates the sidewalls 210 and second surface 211 of the die 208 on the substrate 204 covered with the composite material. Molding 108 the die 208 can include dispensing, flowing, or otherwise providing the composite material 212 so as to cover at least the sidewalls 210 of the die 208 and in some cases the second surface 211 opposite the substrate 204.

Continuing with the sub-method 102, an inductor space is formed 112 in the composite material 212. In the example shown in FIG. 2B, the inductor space is toroidal. This enables a conductive material 216 to encircle the composite material 212 filled with the magnetic material, thus forming an inductor 220, as described below in more detail.

The inductor space can be formed 112 by for example laser drilling, mechanical drilling, or some other subtractive manufacturing technique that removes material from the molded 108 composite material 212 to form a desired shape. As will be appreciated in light of the following description, the configuration and size of the inductor space that is formed 112 is a function of the inductance (or other electrical property for other peripheral devices) desired for operation of the die 208 on the substrate 204 as a functioning module within a computing system. In some examples, the space formed 112 can be a toroid, a polygonal channel, or some other shape circumscribing a pillar of composite material 212.

With continuing reference to FIG. 2B, once the inductor space(s) are formed 112, and inductor can be formed 116 by forming 120 a conductive material 216 is formed 120 within the space, thus encircling a core 218 formed from the magnetic composite material 212 described above. Examples of conductive materials 216 formed 120 in the space include, but are not limited to, copper, copper alloys, aluminum, aluminum alloys, commercial solders (e.g., eutectic alloys of one or more of silver, lead, tin, antimony, and/or copper), commercially available silver paste, among other materials that can be used as a circumscribing conductive structure (e.g., a toroid) around core 218. This produces a module 222 shown in FIG. 2B.

Example techniques used for formation 120 of the conductive material 216 in the inductor space include, but are not limited to, electroless or electrolytic copper plating, sputtering, application (e.g., stencil printing) of solder, solder paste, and/or silver paste, among other techniques. The layer formed of the composite material 212 can be optionally planarized 124 so as to expose the surface of the die 208. A cross-sectional view of an optionally planarized module 222 is shown as module 224 in FIG. 2C. A plan view of the module 224 is shown in FIG. 2D.

In some embodiments, rather than a toroidal inductor space, a “through mold via” (or TMV) is formed 112 in the composite material 212. This alternative configuration for inductor 220′ is illustrated in FIG. 2B′. That is, a trench or hole is formed 112 in the composite material. The conductive material 216 is then formed 120 in the hole or trench so as to form a conductive pillar, which can function as an inductor within the composite material 212.

It will be appreciated the locations of the inductor spaces formed 112 are selected so as to be disposed over an electrical contact to power supply circuitry (or other conductive circuits) within the substrate. In this way, the formation 112 of the inductor space exposes the underlying power circuitry contact, over which can be formed some or all of a conductive metal toroid or pillar. This places the formed inductor in electrical contact with the power circuits of the substrate, thus enabling the inductor to aid in voltage regulation of power supplied to the die 208 via the substrate 204.

Turning now to the sub-method 103 and corresponding structural cross-sections depicted in FIGS. 3A-3D, a die 208 is placed over substrate 204, as described above in the context of the sub-method 102. The description provided above for these elements is equally applicable to this sub-method 103. The substrate 204 and die 208 are coated 109 with a photo-lithographically active material (colloquially referred to as “photoresist”), which is then patterned 113 to form spaces that will be used to form conductive pillars for use in an inductor (or other peripheral device) on the substrate 204. Inductors are then formed 117 in these spaces by, in one embodiment, first forming 119 a conductive metal pillar in the patterned 113 photoresist. In one example, this formation 119 can be accomplished by electroplating copper in the formed 117 space. An alternative technique for “pillar first” formation is that of stencil printing, in which a stencil is used to mask the die and substrate except for locations at which conductive metal pillars are to be formed. A paste of conductive metal (e.g., commercially available solder paste, commercially available silver paste) is then coated over the stencil so as to fill the holes in the stencil, thus forming 119 the conductive metal pillars. The paste of conductive metal can then be heated to remove volatile compounds and cause the particles in the paste to bond together. After formation photoresist (or stencil) can be removed 121 and composite polymer material flowed around the pillars.

Regardless of whether photoresist or a stencil is used, this configuration is shown in FIG. 3B, with pillars 304A, 304B, 304C, and 304D (collectively, 304) shown on the substrate 204 after removal 121 of the photoresist (or stencil). Composite material 212 can then be formed 119 around the conductive metal pillars 304 using any of the techniques and compositions described above.

It will be appreciated that a cross-sectional of the pillar can be in any of a variety shapes. For example, the conductive metal pillar can be formed 119 in a toroidal shape patterned in the photoresist. Composite material 212 can then be flowed around and within the toroid to form 121 inductors 308. As described above, any excess composite material 212 can be removed via planarization 123 from the second surface 211 of the die 208, as shown in FIG. 3D.

The sub-methods 102 and 103 depicted as producing inductors having a circular cross-section (whether of a pillar or a toroid) when taken parallel to the plane of the die 208 it will be appreciated this need not be the case. In other embodiments, the pillar can have any geometric cross-section (e.g., circle, ellipse, regular polygon, irregular polygon). For example, FIG. 3E illustrates a module 228 that includes a periodic array 226 of conductive pillars 232 that have a hexagonal cross-section parallel to the plane of the die 208. This illustrates that not only can the magnetic properties, and size of an inductor be tailored to meet the electrical requirements of a module and the surface area constraints on a module substrate (e.g., substrate 204), but also the cross-sectional shape of a conductive pillar, a number of conductive pillars, and an arrangement (e.g., in a periodic array) of pillars can be tailored to accomplish a particular electrical performance goal (e.g., an inductance value).

### Other Embodiments

As indicated above, removing heat generated from a die during operation can improve reliability and operational performance of integrated circuits. Traditional mold materials formulated from a polymer matrix filled with silica particles (included to improve the mechanical properties and durability of the mold material) often have relatively low thermal conductivity, making removal of heat from a die more difficult. As a result, a temperature of the die can increase leading to performance degradation and long-term reliability problems.

Some embodiments described herein can overcome these challenges. For example, the composite material described above can be used to improve thermal conduction of heat from a die because of, in some cases, a higher thermal conductivity relative to some mold/filler combinations (e.g., polymer filled with silica particles). Furthermore, some of the conductive pillars of the peripheral devices described herein (e.g., inductors) can be configured within the module so as to better transfer heat from the die to an associated thermal sink (e.g., in integrated heat speaker), further increasing the rate of heat conduction from the die.

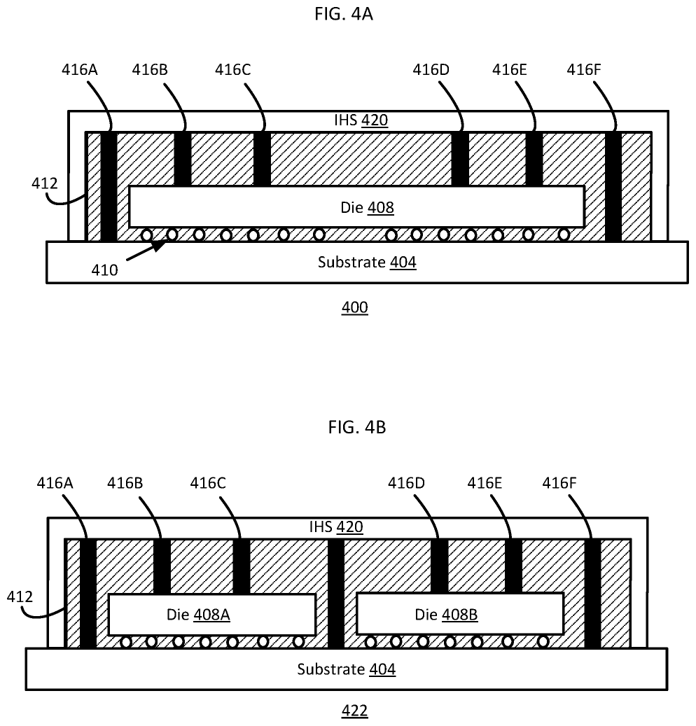

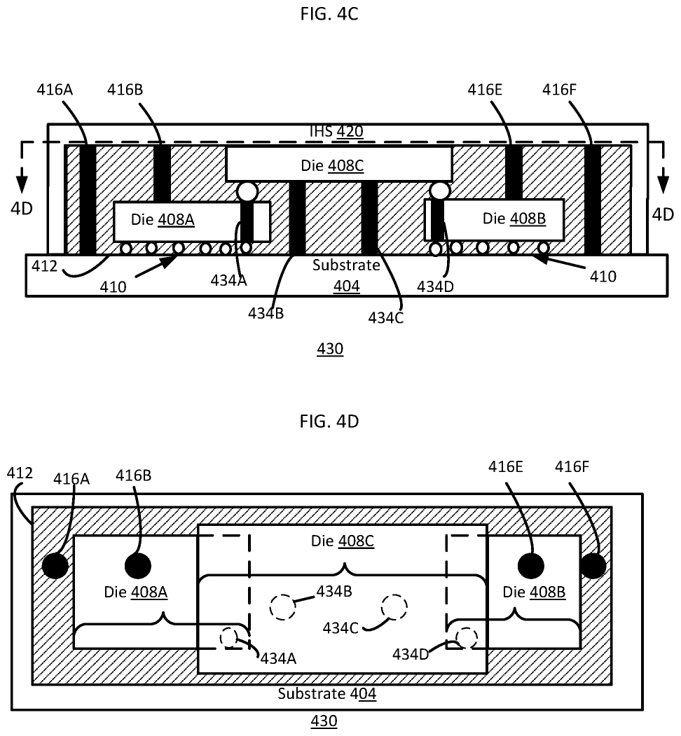

An example of such a configuration is illustrated in FIG. 4A. As shown, an example module 400 includes a substrate 404, a die 408, solder bump interconnections 410, composite material 412, conductive pillars 416A-416F (collectively 416), and integrated heat spreader 420. Although solder bumps (flip-chip bumps) 410 are shown on the bottom of die 408, other configurations may use any number of other suitable interconnection mechanisms (e.g., ball grid array or BGA, pin grid array, dual-inline surface mount, etc.), as will be appreciated.

Many of the elements in the module 400 have been described above and require no further explanation. In addition, it will be noted that some composite materials described herein can have a thermal conductivity of at least 2.7 Watts/meter-Kelvin, at least 10 Watts/meter-Kelvin, or even higher (depending on the composition of the magnetic filler particle, the size of the magnetic filler particles, and the weight percentage (“loading”) of magnetic filler particles in the polymer matrix). The improved thermal conductivity of the composite material 412 (and equivalently composite material 212) is one aspect of some examples of the present disclosure that improves conduction of heat from a die to, for example, the integrated heat spreader (IHS) 420.

Another aspect of some embodiments described herein that further improves the conduction of heat from the die 408 to the integrated heat spreader 420 is the configuration of some of the conductive pillars 416A-416F to be over, and in some cases indirect contact with, the die 408. As shown in FIG. 4A, inductors 416B, 416C, 416D, and 416E are direct contact with both the die 408 and the integrated heat spreader 420. Because the conductive pillars 416 are generally fabricated with an electrically conductive metal that is also thermally conductive, placing at least some of the conductive pillars 416 in contact with a top panel of the integrated heat spreader 420 (to which a heat sink can optionally be attached) can increase heat conduction from the die 408. For the same reasons, the presence of conductive pillars 416A and 416F within the composite material 412 can also increase heat conduction away from the die 408 and to the integrated heat spreader 420.

Management of heat produced within a module becomes more difficult for so-called “multichip modules” (MCM). The multiple die within a multichip module can produce heat at an even higher rate per unit area than that of a single chip module (such as those described above).

As shown in FIG. 4B, thermally and electrically conductive pillars 416 can be placed in contact with multiple die (in this case die 408A, 408B) within a multichip module 422. Heat is removed from the die 408A, 408B by conduction through the conductive pillars 416 and the composite material 412. Thermal conduction through the conductive pillars 416 that are in direct contact with both the die 408A, 408B and the integrated heat spreader 420 can be at a faster rate than those conductive pillars 416A, 416F that are not in direct contact with the die 408A, 408B.

In some embodiments, the conductive pillars and composite material described above need not be fabricated in situ. Rather, a preformed sheet or shell of composite material 412 that includes conductive pillars 416 dimensioned and configured to be placed over and/or in direct contact with the die 408A, 408B and/or in contact with power circuitry contacts on the substrate 404. The preformed sheet or shell of composite material 412 can include, for instance, magnetic particles or fillers as previously explained. As will be further appreciated, the pillars 416 and the sheet or shell of magnetic material collectively serve both as an inductive element as well as a thermal interface material. In some such embodiments, a preformed magnetic sheet that includes one or more pillars passing therethrough and aligned in the z-direction is installed in the package over and/or adjacent the die, before the lid (integrated heat spreader) is attached. The magnetic sheet and pillar arrangement can be, for example, premade at a passive component supplier pursuant to a given specification (e.g., dimensions along with desired inductivity and thermal conductivity), or otherwise provided. In any such cases, the preformed magnetic sheet and pillar arrangement can be attached using standard assembly processes such as pick and place tools or other suitable processes (e.g., manual placement, robotic placement guided with machine vision). In cases that include through molded vias (TMV) connected to underlying substrate power planes or contact points or intervening layers (e.g., organic or inorganic interposer), the preformed magnetic sheet and pillar arrangement can be attached to the TMVs or other upper contact points. Thus, the benefit of improved thermal conduction is combined with convenient manufacturing.

In some embodiments, conductive metal pillars (of any shape or configuration described above) and the magnetically filled composite material can be used as an inductor in a stacked die configuration, as illustrated in FIGS. 4C and 4D. In the example of the module 430, many of the elements are the same as those described above and need no further description. In addition to these previously described elements, an additional die 408C has been added so as to be disposed between die 408A, 408B and IHS 420 and to partially overlap with portions of the die 408A, 408B.

FIGS. 4C and 4D illustrate another embodiment that includes some of the features described above. As shown, in these figures, a module 430 includes die 408A, 408B and 408C in a stacked-die configuration. The die are within composite material 412. Conductive metal pillars 416A and 416F can act as inductors for the die 408A and 408B, as described above. Conductive metal pillars 416B and 416E can act as thermal conductors between the die 408A, 408B and the IHS 420, as also described above.

Using the techniques and materials described above, conductive metal pillars 434B and 434C can be used to electrically connect the substrate 404 to the die 408C. As described above, the conductive metal pillars 434B and 434C within the composite material 412 can act as inductors, thus controlling the characteristics of the power supplied through the substrate 404 to the die 408C in the stacked-die configuration. In some embodiments, this configuration can further reduce the area occupied by a module by incorporating the inductor within the module itself rather than attaching discrete surface mounted inductors. Furthermore, it will be appreciated the conductive metal pillars 434A, 434B, 434C, and 434D can also be used to conduct heat and/or provide inductance (or other peripheral device function if so configured), as described above.

Conductive metal pillars 434A and 434D can be plated through-silicon vias to connect the substrate to the die 408C through the die 408A, 408B (and through intervening solder bumps). As will be appreciated, in various examples the die 408A, 408C can be either active die (e.g., including operating integrated circuits) or passive die (i.e., a semiconductor interposer).

Example System

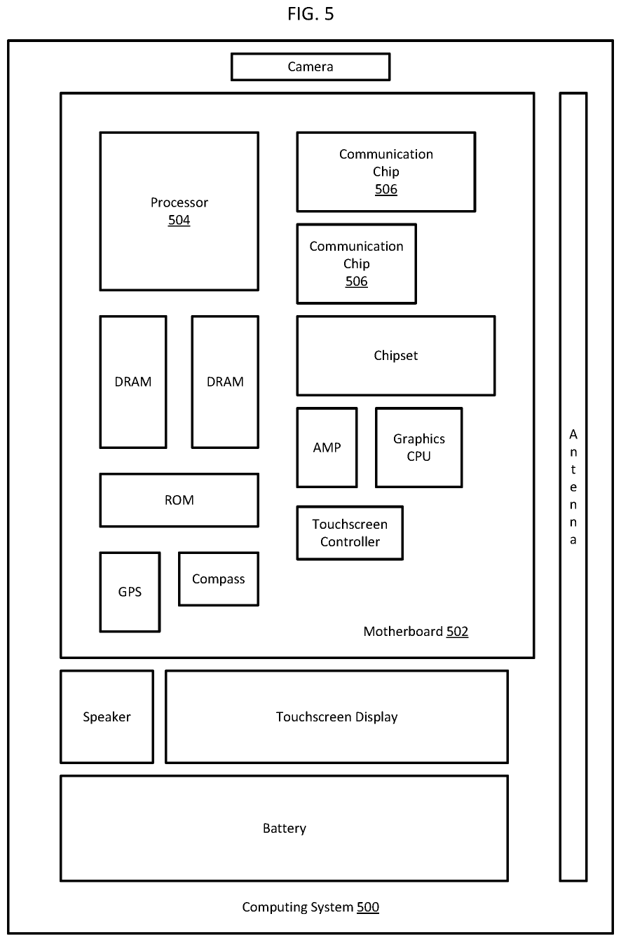

FIG. 5 is an example computing system implemented with one or more of the integrated circuit structures as disclosed herein, in accordance with some embodiments of the present disclosure. As can be seen, the computing system 500 houses a motherboard 502. The motherboard 502 may include a number of components, including, but not limited to, a processor 504 and at least one communication chip 506, each of which can be physically and electrically coupled to the motherboard 502, or otherwise integrated therein. As will be appreciated, the motherboard 502 may be, for example, any printed circuit board, whether a main board, a daughterboard mounted on a main board, or the only board of system 500, etc.

Depending on its applications, computing system 500 may include one or more other components that may or may not be physically and electrically coupled to the motherboard 502. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 500 may include one or more integrated circuit structures or devices configured in accordance with an example embodiment (e.g., to include modules with peripheral devices disposed on a module substrate as described above). In some embodiments, multiple functions can be integrated into one or more chips (e.g., for instance, note that the communication chip 506 can be part of or otherwise integrated into the processor 504).

The communication chip 506 enables wireless communications for the transfer of data to and from the computing system 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others. In some embodiments, communication chip 506 may include one or more transistor structures having a gate stack an access region polarization layer as variously described herein.

The processor 504 of the computing system 500 includes an integrated circuit die packaged within the processor 504. In some embodiments, the integrated circuit die of the processor includes onboard circuitry that is implemented with one or more integrated circuit structures or devices as variously described herein. The term “processor” may refer to any device or portion of a device that processes, for instance, electronic data from registers and/or memory to transform that electronic data into other electronic data that may be stored in registers and/or memory.

The communication chip 506 also may include an integrated circuit die packaged within the communication chip 506. In accordance with some such example embodiments, the integrated circuit die of the communication chip includes one or more integrated circuit structures or devices as variously described herein. As will be appreciated in light of this disclosure, note that multi-standard wireless capability may be integrated directly into the processor 504 (e.g., where functionality of any chips 506 is integrated into processor 504, rather than having separate communication chips). Further note that processor 504 may be a chip set having such wireless capability. In short, any number of processor 504 and/or communication chips 506 can be used. Likewise, any one chip or chip set can have multiple functions integrated therein.

In various implementations, the computing system 500 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

### Further Example Embodiments

The following examples pertain to further embodiments, from which numerous permutations and configurations will be apparent.

Example 1 is an electronic package comprising a substrate; a die over the substrate, the die comprising a first side confronting the substrate, a second side opposite the first side, and sidewalls between the first side and the second side; a layer comprising a composite material on the substrate and around the die in contact with at least a portion of the sidewalls of the die, the composite material comprising a polymer matrix and magnetic filler particles; and at least one pillar comprising a conductive material in the composite material.

Example 2 includes the subject matter of Example 1, further comprising, conductive circuits associated with the substrate, wherein the pillar is electrically connected to the conductive circuits.

Example 3 includes the subject matter of Example 1 or 2, wherein the pillar is around a portion of the layer of the composite material.

Example 4 includes the subject matter of any of the preceding Examples, wherein the pillar is a toroid around a portion of the layer of the composite material, the toroid and the portion of the composite material forming an inductor.

Example 5 includes the subject matter of any of the preceding Examples, wherein the layer comprising the composite material of the layer is around the at least one pillar, the composite material and the at least one pillar forming at least one inductor.

Example 6 includes the subject matter of any of the preceding Examples, wherein the at least one pillar comprises a plurality of pillars in a periodic array.

Example 7 includes the subject matter of any of the preceding Examples, wherein the at least one pillar has a regular polygon cross-section, and the composite material of the layer is around the pillar.

Example 8 includes the subject matter of Example 7, wherein the regular polygon cross-section is hexagonal.

Example 9 includes the subject matter of any of the preceding Examples, wherein the magnetic filler particles comprise a ferromagnetic magnetic material.

Example 10 includes the subject matter of Example 9, wherein the ferromagnetic magnetic material comprises zinc and one of manganese or nickel.

Example 11 includes the subject matter of Example 9, wherein the ferromagnetic magnetic material comprises iron and oxygen.

Example 12 includes the subject matter of any of the preceding Examples, wherein the magnetic filler particles comprise a soft magnetic material having a magnetic coercivity of less than 1000 Amperes/meter.

Example 13 includes the subject matter of any of the preceding Examples, wherein the magnetic filler particles comprise iron and at least one of silicon, nickel, and cobalt.

Example 14 includes the subject matter of any of the preceding Examples, wherein the magnetic filler particles have a particle diameter of from 0.1 μm to 10 μm in diameter.

Example 15 includes the subject matter of any of the preceding Examples, wherein the composite material has a thermal conductivity of at least 2.7 Watts/meter-Kevin.

Example 16 includes the subject matter of any of the preceding Examples, further comprising an integrated heat spreader that includes sidewalls in contact with the substrate and a top panel in contact with at least one conductive pillar.

Example 17 includes the subject matter of any of the preceding Examples, wherein a pillar of the at least one pillar is in contact with both the top panel of the integrated heat spreader and the die.

Example 18 includes the subject matter of any of the preceding Examples, wherein the die comprises a first die and a second die.

Example 19 includes the subject matter of any of the preceding Examples, wherein the magnetic filler particles comprise from 40 volume % to 90 volume % of the composite material.

Example 20 is an electronic package comprising: a substrate comprising at least one conductive circuit; a die over the substrate, the die comprising a first side confronting the substrate, a second side opposite the first side, and sidewalls between the first side and the second side; a layer comprising a composite material on the substrate and around the die in contact with at least a portion of the sidewalls of the die, the composite material comprising a polymer matrix and magnetic filler particles; and at least one pillar comprising a conductive material, the at least one pillar in the layer comprising the composite material and electrically connected to the at least one conductive circuit.

Example 21 includes the subject matter of either of Example 20, wherein the magnetic filler particles comprise a ferromagnetic magnetic material.

Example 22 includes the subject matter of any of Examples 20 or 21, wherein the at least one pillar is around a portion of the layer of the composite material.

Example 23 includes the subject matter of Example 22, wherein the pillar is a toroid around a portion of the layer of the composite material, the toroid and the portion of the composite material forming an inductor.

Example 24 includes the subject matter of any of Examples 20-23, wherein the layer comprising the composite material is around the at least one pillar, the composite material and the at least one pillar forming at least one inductor.

Example 25 is an electronic package comprising a substrate; a die over the substrate, the die comprising a first side confronting the substrate, a second side opposite the first side, and sidewalls between the first side and the second side; a layer comprising a composite material on the substrate and around the die in contact with at least a portion of the sidewalls of the die, the composite material comprising a polymer matrix and magnetic filler particles; at least one pillar comprising a conductive material in the composite material; and an integrated heat spreader that includes sidewalls in contact with the substrate and a top panel in contact with at least one conductive pillar.

Example 26 includes the subject matter of Example 25, wherein the at least one pillar comprises copper.

Example 27 includes the subject matter of any of Examples 25-26, wherein a pillar of the at least one pillar is in contact with both the top panel of the integrated heat spreader and the die.

Example 28 includes the subject matter of any of Examples 25-27, wherein the composite material of the layer of the composite material has a thermal conductivity of at least 2.7 Watts/meter-Kevin.

Example 29 includes the subject matter of any of Examples 25-28, wherein the layer comprising the composite material is around the at least one pillar, the composite material and the at least one pillar forming at least one inductor.

Example 30 is a motherboard that includes the subject matter of any of the preceding Examples.

Example 31 is a computing system that includes the subject matter of any of the preceding Examples.

What is claimed is:

1. An electronic package comprising:
a substrate;
a die over the substrate, the die comprising a first side confronting the substrate, a second side opposite the first side, and sidewalls between the first side and the second side;
a layer comprising a composite material on the substrate and around the die in contact with at least a portion of the sidewalls of the die, the composite material comprising a polymer matrix and magnetic filler particles; and
at least one pillar comprising a conductive material in the composite material.

2. The electronic package of claim 1, wherein the at least one pillar comprises a plurality of pillars in a periodic array.

3. The electronic package of claim 1, wherein the at least one pillar has a regular polygon cross-section, and the composite material of the layer is around the pillar.

4. The electronic package of claim 3, wherein the regular polygon cross-section is hexagonal.

5. The electronic package of claim 1, wherein the magnetic filler particles comprise a ferromagnetic magnetic material.

6. The electronic package of claim 5, wherein the ferromagnetic magnetic material comprises zinc and one of manganese or nickel.

7. The electronic package of claim 5, wherein the ferromagnetic magnetic material comprises iron and oxygen.

8. The electronic package of claim 1, wherein the magnetic filler particles comprise a soft magnetic material having a magnetic coercivity of less than 1000 Amperes/meter.

9. The electronic package of claim 1, wherein the magnetic filler particles comprise iron and at least one of silicon, nickel, and cobalt.

10. The electronic package of claim 1, wherein the composite material of the layer of the composite material has a thermal conductivity of at least 2.7 Watts/meter-Kevin.

11. A motherboard comprising the electronic package of claim 1.

12. A computing system comprising the electronic package of claim 1.

13. An electronic package comprising:
a substrate comprising at least one conductive circuit;
a die over the substrate, the die comprising a first side confronting the substrate, a second side opposite the first side, and sidewalls between the first side and the second side;
a layer comprising a composite material on the substrate and around the die in contact with at least a portion of the sidewalls of the die, the composite material comprising a polymer matrix and magnetic filler particles; and
at least one pillar comprising a conductive material, the at least one pillar in the layer comprising the composite material and electrically connected to the at least one conductive circuit.

14. The electronic package of claim 13, wherein the magnetic filler particles comprise a ferromagnetic magnetic material.

15. The electronic package of claim 13, wherein the at least one pillar is around a portion of the layer of the composite material.

16. The electronic package of claim 15, wherein the pillar is a toroid around a portion of the layer of the composite material, the toroid and the portion of the composite material forming an inductor.

17. The electronic package of claim 13, wherein the layer comprising the composite material is around the at least one pillar, the composite material and the at least one pillar forming at least one inductor.

18. An electronic package comprising:
a substrate;
a die over the substrate, the die comprising a first side confronting the substrate, a second side opposite the first side, and sidewalls between the first side and the second side;
a layer comprising a composite material on the substrate and around the die in contact with at least a portion of the sidewalls of the die, the composite material comprising a polymer matrix and magnetic filler particles;
at least one pillar comprising a conductive material in the composite material; and
an integrated heat spreader that includes sidewalls in contact with the substrate and a top panel in contact with at least one conductive pillar.

19. The electronic package of claim 18, wherein a pillar of the at least one pillar is in contact with both the top panel of the integrated heat spreader and the die.

20. The electronic package of claim 18, wherein the composite material of the layer of the composite material has a thermal conductivity of at least 2.7 Watts/meter-Kevin.
